(19) United States
(12) Patent Application Publication
(10) Pub. No.: US 2023/0225172 A1
(43) Pub. Date: Jul. 13, 2023

(54) DISPLAY PANEL

(71) Applicant: SAMSUNG DISPLAY CO., LTD., Yongin-si (KR)

(72) Inventors: Chiwook An, Yongin-si (KR); Beohmrock Choi, Yongin-si (KR); Hyunduck Cho, Yongin-si (KR); Miran Ji, Yongin-si (KR); Hyeonbum Lee, Yongin-si (KR)

(21) Appl. No.: 17/983,779

(22) Filed: Nov. 9, 2022

(30) Foreign Application Priority Data
Jan. 10, 2022 (KR) 10-2022-0003629

(51) Int. Cl. H01L 27/32; H01L 51/52

(52) U.S. Cl. CPC H01L 27/322; H01L 51/5281; H01L 51/5253; H01L 27/3244

(57) ABSTRACT

A display panel includes: a substrate; a plurality of display elements disposed over the substrate; a plurality of first light-blocking layers disposed over the plurality of display elements and corresponding to places between the plurality of display elements; a plurality of second light-blocking layers disposed over the plurality of first light-blocking layers and corresponding to the places between the plurality of display elements; and a color filter layer disposed over the plurality of second light-blocking layers and including color filters corresponding to the plurality of display elements.

This application claims priority to Korean Patent Application No. 10-2022-0003629, filed on Jan. 10, 2022, and all the benefits accruing therefrom under 35 U.S.C. § 119, the content of which in its entirety is herein incorporated by reference.

### BACKGROUND

### 1. Field

One or more embodiments relate to a display panel, and more particularly, to a display panel which has an increased user convenience and which may be easily manufactured.

### 2. Description of the Related Art

Generally, a display panel may display images by including display elements. The display panel may be utilized in various forms. For example, the display panel may be used in various electronic apparatuses such as smartphones, digital cameras, laptop computers, navigation apparatuses, or smart televisions, and used in a display unit of other apparatuses.

### SUMMARY

However, a display panel according to a related art has a disadvantage of low user convenience.

One or more embodiments include a display panel which has an increased user convenience and which is easily manufactured. However, such a technical problem is an example, and the disclosure is not limited thereto.

Additional aspects will be set forth in part in the description which follows and, in part, will be apparent from the description, or may be learned by practice of the presented embodiments of the disclosure.

According to one or more embodiments, a display panel includes: a substrate, a plurality of display elements disposed over the substrate, a plurality of first light-blocking layers disposed over the plurality of display elements and corresponding to places between the plurality of display elements, a plurality of second light-blocking layers disposed over the plurality of first light-blocking layers and corresponding to the places between the plurality of display elements, and a color filter layer disposed over the plurality of second light-blocking layers and including color filters corresponding to the plurality of display elements.

The plurality of first light-blocking layers may be connected to each other, and the plurality of second light-blocking layers may be connected to each other.

Each of the plurality of first light-blocking layers may extend substantially in a first direction, and the plurality of first light-blocking layers may be arranged in a second direction crossing the first direction, and each of the plurality of second light-blocking layers may extend in the first direction, and the plurality of second light-blocking layers may be arranged in the second direction.

Among the plurality of display elements, each of display elements arranged on one row extending in the first direction may emit light of a wavelength belonging to a same wavelength band.

A width of each of the plurality of display elements in the second direction may be the same.

The plurality of display elements may include first display elements arranged on a first row extending in the first direction, second display elements arranged on a second row extending in the first direction, and third display elements arranged on a third row extending in the first direction, and wherein a first length of the first display elements in the first direction, a second length of the second display elements in the first direction, and a third length of the third display elements in the first direction may be different from one another.

The first display elements may emit red light, the second display elements may emit green light, and the third display elements may emit blue light, wherein the first length may be greater than the second length and less than the third length.

The color filters include first color filters arranged on a first row extending in the first direction, second color filters arranged on a second row extending in the first direction, and third color filters arranged on a third row extending in the first direction, and wherein a first length of the first color filters in the first direction, a second length of the second color filters, and a third length of the third color filters in the first direction may be different from one another.

The first color filters may transmit red light, the second color filters may transmit green light, and the third color filters may transmit blue light, wherein the first length may be greater than the second length and less than the third length.

The plurality of display elements may include first display elements arranged on a first row extending in the first direction, second display elements arranged on a second row extending in the first direction, and third display elements arranged on a third row extending in the first direction, wherein a first length of the first display elements in the first direction, a second length of the second display elements in the first direction, and a third length of the third display elements in the first direction may be the same.

The color filters include first color filters arranged on the first row, second color filters arranged on the second row, and third color filters arranged on the third row, wherein the first color filters may have a first transmittance, the second color filters may have a second transmittance, and the third color filters may have a third transmittance, and wherein the first transmittance, the second transmittance, and the third transmittance may be different from one another.

The first color filters may transmit red light, the second color filters may transmit green light, and the third color filters may transmit blue light, wherein the first transmittance may be greater than the second transmittance and less than the third transmittance.

In a plan view, the plurality of second light-blocking layers may overlap the plurality of first light-blocking layers.

The color filter layer may further include a color light-blocking layer between the color filters.

The plurality of first light-blocking layers may be inside the color light-blocking layer, and the plurality of second light-blocking layers may be inside the color light-blocking layer in the plan view.

The display panel may further include a sensor electrode layer disposed between the plurality of second light-blocking layers and the color filter layer.

An electrode of the sensor electrode layer in a display area may overlap the plurality of second light-blocking layers in the plan view.

The color filter layer may further include a color light-blocking layer between the color filters, and an electrode of the sensor electrode layer in a display area may be arranged between the plurality of second light-blocking layers and the color light-blocking layer.

The display panel may further include an encapsulation layer covering the plurality of display elements, wherein the plurality of first light-blocking layers may be disposed on the encapsulation layer.

The display panel may further include a first organic material layer covering the plurality of first light-blocking layers, and a second organic material layer covering the plurality of second light-blocking layers, wherein the plurality of second light-blocking layers may be disposed on the first organic material layer, and the color filter layer may be disposed on the second organic material layer.

These and/or other aspects will become apparent and more readily appreciated from the following description of the embodiments, the accompanying drawings, and claims.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a portion of a display module including a display panel according to an embodiment;

FIG. 2 is a schematic side view of a portion of the display module of FIG. 1;

FIG. 3 is a schematic plan view of a portion of the display module of FIG. 1;

FIG. 4 is a schematic conceptual view of a portion of FIG. 3;

FIG. 5 is a detailed enlarged plan view of a portion of FIG. 4;

FIG. 6 is a detailed enlarged plan view of a portion of FIG. 5;

FIG. 7 is a schematic cross-sectional view of the display module, taken along line I-I′ of FIG. 6;

FIG. 8 is a schematic cross-sectional view of a display panel according to an embodiment;

FIG. 9 is a schematic plan view of a portion of a display panel according to an embodiment;

FIG. 10 is a schematic plan view of a portion of a display panel according to an embodiment;

FIG. 11 is a schematic plan view of a portion of a display panel according to an embodiment;

FIG. 12 is a schematic plan view of a portion of a display panel according to an embodiment; and

FIG. 13 is a schematic plan view of a portion of a display panel according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “Or” means “and/or.” As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

As the present disclosure allows for various changes and numerous embodiments, certain embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein. Hereinafter, embodiments will be described with reference to the accompanying drawings, wherein like reference numerals refer to like elements throughout and a repeated description thereof is omitted.

It will be understood that, when a layer, region, or component is referred to as being “on” another layer, region, or component, it can be directly or indirectly on the other layer, region, or component. That is, for example, intervening layers, regions, or components may be present. Sizes of elements in the drawings may be exaggerated or reduced for convenience of explanation. For example, since sizes and thicknesses of elements in the drawings are arbitrarily illustrated for convenience of explanation, the disclosure is not limited thereto.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

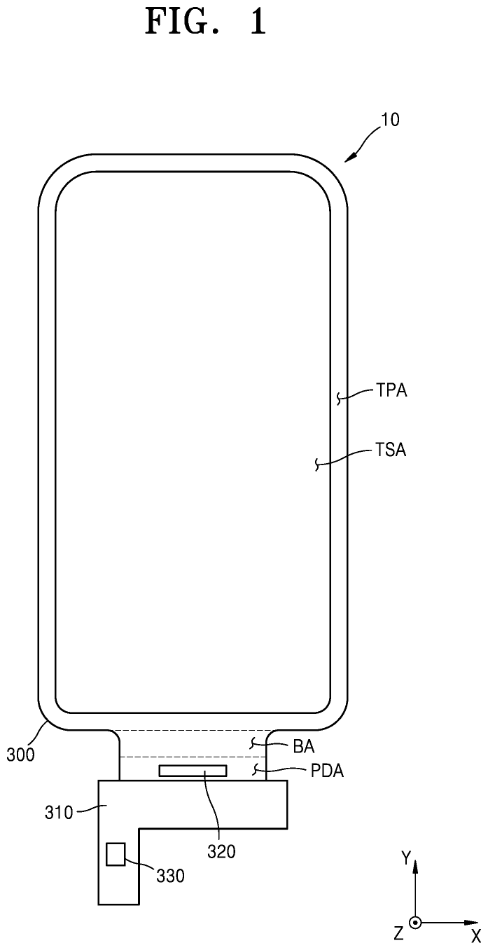

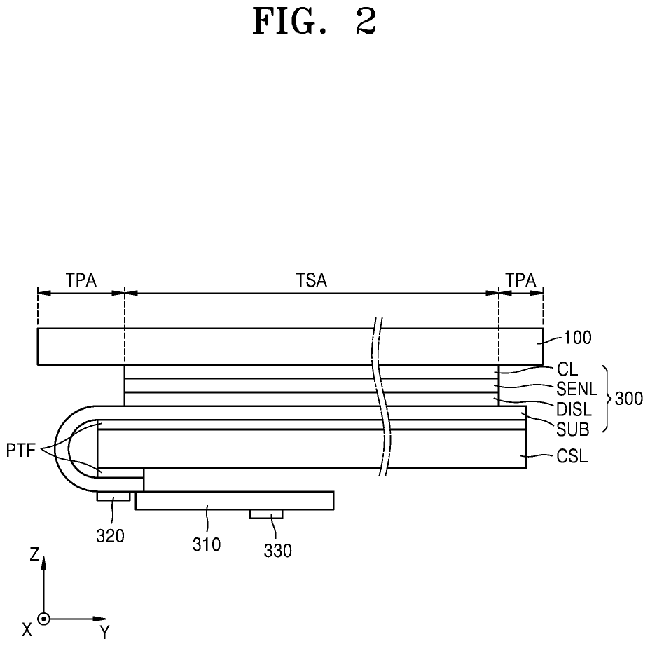

FIG. 1 is a schematic plan view of a portion of a display module 10 including a display panel 300 according to an embodiment, and FIG. 2 is a schematic side view of a portion of the display module 10 of FIG. 1. It is shown in FIG. 2 that a substrate SUB is flexible, and the display panel 300 has a bent shape in a bent area BA (see FIG. 1). For convenience of description, FIG. 1 shows the display panel 300 that is not bent.

Referring to FIGS. 1 and 2, the display module 10 including the display panel 300 according to an embodiment may display moving images or still images, and be used in portable electronic apparatuses including mobile phones, smart phones, tablet personal computers (“PC”), mobile communication terminals, electronic organizers, electronic books, portable multimedia players (“PMP”), navigations, and ultra mobile personal computers (“UMPC”). In addition, the display module 10 may be used in various products including televisions, notebook computers, monitors, advertisement boards, Internet of things (“IoT”), and the like. In addition, the display module 10 may be used in wearable devices including smartwatches, watchphones, glasses-type displays, or head-mounted displays (“HMD”). In addition, the display module 10 may be used as instrument panels for automobiles, center fascias for automobiles, or center information displays (“CID”) arranged on a dashboard, room mirror displays that replace side mirrors of automobiles, or displays arranged on the backside of front seats as an entertainment for back seats of automobiles.

The display module 10 including the display panel 300 according to an embodiment may include a cover window 100, the display panel 300, a display circuit board 310, a display driver 320, a sensor driver 330, a protection film PTF that is patterned, and a cushion layer CSL. In addition, the display module 10 may further include a bracket or a main circuit board not shown.

Hereinafter, an “upper direction” denotes a direction in which the cover window 100 is disposed with respect to the display panel 300, and a “lower direction” denotes a direction opposite thereto with respect to the display panel 300. In addition, “left” and “right” denote directions based on when the display panel 300 is viewed in a direction perpendicular to the display panel 300. As an example, “left” denotes a −x direction, and “right” denotes a +x direction.

The display module 10 may have an approximately rectangular shape when viewed in a direction perpendicular to a surface thereof (i.e., plan view) as shown in FIG. 1. As an example, the display module 10 may have a rectangular planar shape entirely, wherein the rectangular planar shape has short sides extending in a first direction (an x-axis direction) and long sides extending in a second direction (a y-axis direction). An edge where the short side in the first direction meets the long side in the second direction may have a round shape with a preset curvature, or a right angled shape. In addition, the planar shape of the display module 10 is not limited to rectangular shapes but may have other polygons, circular shapes, or elliptical shapes in another embodiment.

As shown in FIG. 2, the cover window 100 may be disposed on the display panel 300 to cover the upper surface of the display panel 300. The cover window 100 may protect the upper surface of the display panel 300.

The display panel 300 may be disposed under the cover window 100. The display panel 300 may overlap a transmission portion of the cover window 100 in a plan view. The display panel 300 may include the substrate SUB and display elements disposed over the substrate SUB. It is shown in FIG. 2 that the display panel 300 includes the substrate SUB, a display layer DISL, a sensor electrode layer SENL, and a color filter layer CL.

The display panel 300 displays (outputs) information processed by the display module 10. As an example, the display panel 300 may display execution screen information of an application driven by the display module 10, or user interface (“UI”) and graphic user interface (“GUI”) information corresponding to the execution screen information. The display panel 300 may include the display layer DISL and the sensor electrode layer SENL, wherein the display layer DISL displays images, and the sensor electrode layer SENL senses a user's touch input. Accordingly, the display panel 300 serves as an input unit providing an input interface between the display module 10 and a user, and simultaneously, serves as an output unit providing an output interface between the display module 10 and a user.

The substrate SUB of the display panel 300 may include an insulating material such as glass, quartz, or a polymer resin. The substrate SUB may be a rigid substrate or a flexible substrate that is bendable, foldable, and rollable. It is shown in FIG. 2 that the substrate SUB is flexible, and has a shape in which the display panel 300 is bent in the bent area BA (see FIG. 1). For reference, though it is shown in FIG. 2 that only the substrate SUB is bent, the embodiment is not limited thereto. At least a portion of the display layer DISL and at least a portion of the sensor electrode layer SENL may be also present in the bent area BA (see FIG. 1) and a pad area in another embodiment. In this case, a portion of the display layer DISL and a portion of the sensor electrode layer SENL may be also bent in the bent area BA.

The substrate SUB may include a display area and a peripheral area outside the display area. A plurality of display elements are arranged in the display area of the substrate SUB. The display layer DISL of FIG. 2 may be a layer including display elements arranged over the substrate SUB. Specifically, the display layer DISL may include a thin-film transistor layer, a display element layer, an encapsulation layer, a plurality of first light-blocking layers, and a plurality of second light-blocking layers, wherein the thin-film transistor layer includes thin-film transistors, the display element layer includes display elements such as organic light-emitting elements, and the encapsulation layer encapsulates the display element layer.

The peripheral area of the substrate SUB may be a region in which images are not displayed. The peripheral area may surround the display area. The peripheral area may be a region from the edge of the display area to the edge of the display panel 300. Not only display elements but scan lines, data lines, or power lines connected to the display elements may be arranged in the display area. A scan driver, fan-out wirings and the like may be arranged in the peripheral area, wherein the scan driver is configured to apply scan signals to the scan lines, and the fan-out wirings connect the data lines to the display driver 320.

The display elements may include, for example, light-emitting elements. Specifically, the display panel 300 may be an organic light-emitting display panel including an organic light-emitting diode that includes an organic emission layer, an ultra-miniature light-emitting diode display panel that uses a micro light-emitting diode, a quantum-dot light-emitting display panel that uses a quantum-dot light-emitting diode including a quantum-dot emission layer, or an inorganic light-emitting display panel that uses an inorganic light-emitting element including an inorganic semiconductor.

As shown in FIGS. 1 and 2, the sensor electrode layer SENL may include a sensor area TSA and a sensor peripheral area TPA. The sensor area TSA in which sensor electrodes are arranged may be a region configured to sense a user's touch input. The sensor peripheral area TPA may have a shape surrounding the sensor area TSA. The sensor peripheral area TPA may be a region from the edge of the sensor area TSA to the edge of the display panel 300. Sensor electrodes, connectors, and conductive patterns may be arranged in the sensor area TSA. Sensor lines connected to the sensor electrodes may be arranged in the sensor peripheral area TPA.

As described above, the substrate SUB of the display panel 300 includes the display area and the peripheral area outside the display area. The sensor area TSA may overlap the display area, and the sensor peripheral area TPA may overlap the peripheral area in a plan view. In addition, the peripheral area outside the display area may be a wider area including the sensor peripheral area TPA.

The sensor electrode layer SENL may sense a user's touch input by using at least one of various touch methods such as a resistance layer method, a capacitance method and the like. As an example, in the case where the sensor electrode layer SENL senses a user's touch input by using a capacitance method, the sensor driver 330 may be configured to determine whether a user touches by applying driving signals to driving electrodes among sensor electrodes, and sensing voltages charged in a mutual capacitance between the driving electrodes and sensing electrodes through the sensing electrodes among the sensor electrodes.

A user's touch may include a contact touch and a proximity touch. A contact touch denotes that an object such as a user's finger or a pen directly contacts the cover window 100 disposed on the sensor electrode layer. A proximity touch, like hovering, denotes that an object such as a user's finger or a pen is located near above the cover window 100 but away from the cover window 100. The sensor driver 330 may be configured to transfer sensor data to a main processor according to sensed voltages, and the main processor may calculate a touch coordinate at which a touch input occurs by analyzing the sensor data.

The color filter layer CL may be disposed on the sensor electrode layer SENL. The color filter layer CL may reduce external light reflection. This is described below.

It is shown in FIG. 2 that the display panel 300 is bendable and bent in the bent area BA. However, the embodiment is not limited thereto. As an example, the display panel 300 may be a foldable display panel that is folded and unfolded, a curved display panel in which at least a portion of a display surface is curved, a bended display panel in which a region except a display surface is bent, a rollable display panel that is rolled and unrolled, or a stretchable display panel that is stretchable in another embodiment. Alternatively, the display panel 300 may be a rigid display panel that has rigidity and is not easily bent.

In the case where the display panel 300 is bent in the bent area BA, the bent area BA and a pad area PDA may protrude in a second direction (a y-axis direction) from the sensor peripheral area TPA on one side of the display panel 300 (see FIG. 1). For reference, though it is shown in FIGS. 1 and 2 that the length of the bent area BA and the pad area PDA in the first direction (the x-axis direction) is less than the length of the sensor area TSA in the first direction (the x-axis direction), the embodiment is not limited thereto. As described above, in the case where the display panel 300 is bent, the pad area PDA may be disposed below (a −z direction) another portion of the display panel 300. In addition, the pad area PDA may overlap the sensor area TSA in the thickness direction (a z-axis direction) of the display panel 300 (i.e., plan view). The display driver 320 and the display circuit board 310 may be arranged in the pad area PDA.

The display driver 320 may receive control signals and power voltages, generates and outputs signals and voltages for driving the display panel 300. The display driver 320 may include an integrated circuit (“IC”).

The display circuit board 310 may be electrically connected to the display panel 300. The display circuit board 310 may be a flexible printed circuit board (“FPCB”) that may be bent, or a rigid printed circuit board (“PCB”) that is strong and not easily bent. Depending on the case, the display circuit board 310 may be a composite printed circuit board including both a rigid printed circuit board and a flexible printed circuit board.

The sensor driver 330 may be disposed on the display circuit board 310. The sensor driver 330 may include an integrated circuit. The sensor driver 330 may be electrically connected to the sensor electrodes of the sensor electrode layer of the display panel 300 through the display circuit board 310.

In addition, a power supply unit may be additionally disposed on the display circuit board 310, wherein the power supply unit is configured to supply driving voltages for driving pixels of the display panel 300, the scan driver, and the display driver 320. Alternatively, the power supply unit may be integrated with the display driver 320. In this case, the display driver 320 and the power supply unit may be implemented in one integrated circuit.

The display circuit board 310 may be electrically connected to a main circuit board not shown. The main circuit board may include, for example, a main processor including an IC, a camera apparatus, a wireless communication unit, an input unit, an output unit, an interface, a memory, and/or a power supply unit.

The protection film PTF that is patterned may be attached on the backside of the substrate SUB. That is, the protection film PTF that is patterned is attached on the backside of the substrate SUB and attached on a portion except the bent area of the substrate SUB. The protection film PTF that is patterned may include a first part and a second part, wherein the first part corresponds to a portion including the central portion of the substrate SUB, and the second part is apart from the first part and corresponds to an edge portion on one side of the substrate SUB. The cushion layer CSL may be disposed between the first part and the second part of the protection film PTF that is patterned.

The cushion layer CSL prevents the display panel 300 from being destroyed by absorbing external impacts. A buffering member may have a single-layered structure or a multi-layered structure. As an example, the buffering member may include a polymer resin such as polyurethane, polycarbonate, polypropylene, polyethylene, and the like, or include an elastic material such as rubber, a urethane-based material, a sponge foam-molded with an acryl-based material, and the like.

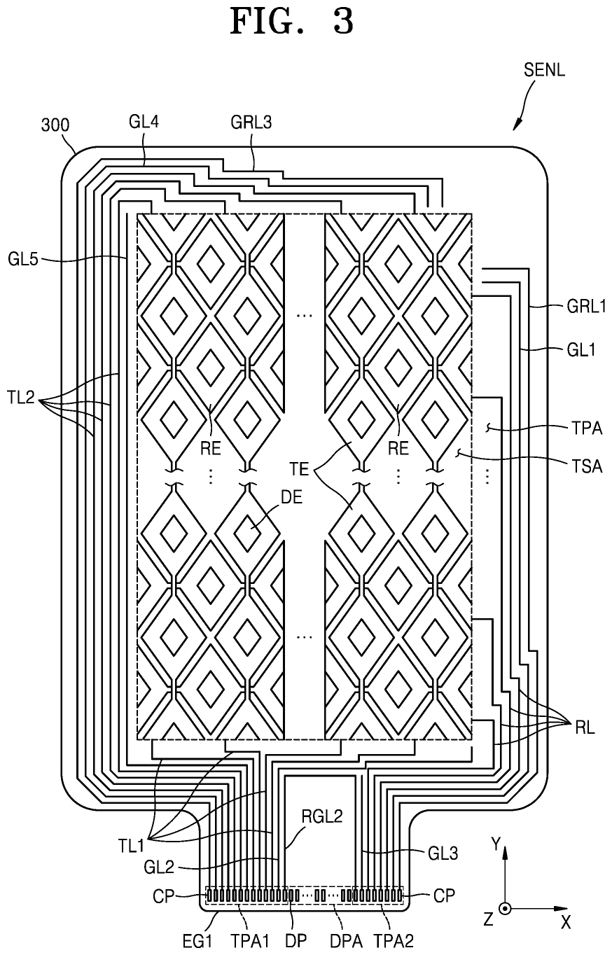

FIG. 3 is a schematic plan view of a portion of the display module 10 of FIG. 1, and specifically, is a schematic plan view of the sensor electrode layer SENL of the display panel 300. Though it is shown, for convenience of description, in FIG. 3 that the sensor electrode layer SENL is flat, a portion of the sensor electrode layer SENL may be bent in the bent area BA as described with reference to FIG. 2.

It is shown in FIG. 3 that the sensor electrode layer SENL includes two kinds of electrodes, for example, driving electrodes TE and sensing electrodes RE. Hereinafter, the case where the sensor electrode layer SENL is driven in a mutual capacitance method of two layers is mainly described, wherein the mutual capacitance method of two layers is configured to apply driving signals to the driving electrodes TE and then sense voltages charged in mutual capacitances through the sensing electrodes RE. For reference, for convenience of description and for convenience of illustration, FIG. 3 shows only the sensor electrodes TE and RE, dummy patterns DE, sensor lines TL1, TL2, and RL, sensor pad areas TPA1 and TPA2, guard lines GL1, GL2, GL3, GL4, and GL5, and ground lines CRL1, CRL2, and CRL3.

For reference, conductive pads CP may be arranged on one side (a −x direction) of a first sensor pad area TPA1 and another side (a x direction) of a second sensor pad area TPA2. The conductive pad CP may be electrically connected to the display circuit board 310 to allow conductive patterns on the substrate are electrically connected to the display circuit board 310. A display pad DP may be arranged in a display pad area DPA between the first and second sensor pad areas TPA1 and TPA2. The display driver 320 may be electrically connected to the display circuit board 310 through the display pad DP.

Referring to FIG. 3, the sensor electrode layer SENL includes the sensor area TSA and the sensor peripheral area TPA, wherein the sensor area TSA is configured to sense a user's touch, and the sensor peripheral area TPA is arranged around the sensor area TSA. As described above, the substrate SUB of the display panel 300 includes the display area and the peripheral area outside the display area. The sensor area TSA may overlap the display area, and the sensor peripheral area TPA may overlap the peripheral area in a plan view. In addition, the peripheral area outside the display area may be a wider area including the sensor peripheral area TPA.

The sensor electrode layer SENL may include first sensor electrodes TE and second sensor electrodes RE. Hereinafter, the case where the first sensor electrode is the driving electrode TE, and the second sensor electrode is the sensing electrode RE is described. Though it is shown in FIG. 3 that each of the driving electrodes TE, the sensing electrodes RE, and the dummy patterns DE has a rhombus shape, the embodiment is not limited thereto.

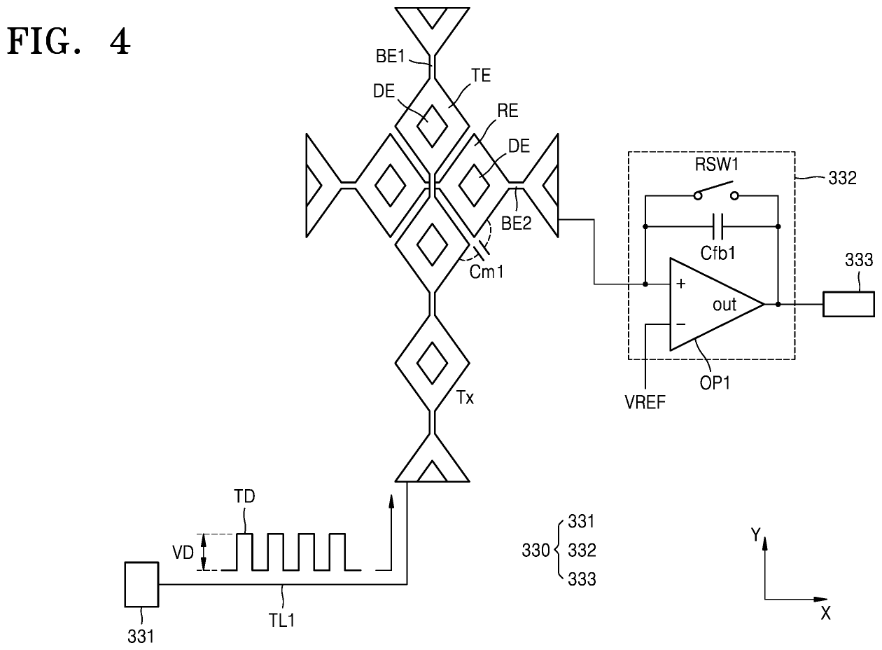

The sensing electrodes RE may be arranged in the first direction (the x-axis direction) and electrically connected to each other. The driving electrodes TE may be arranged in the second direction (the y-axis direction) crossing the first direction and electrically connected to each other. The driving electrodes TE may be electrically separated from the sensing electrodes RE. The driving electrodes TE may be arranged apart from the sensing electrodes RE. For the sensing electrodes RE to be electrically separated from the driving electrodes TE in intersection regions thereof, the driving electrodes TE adjacent to each other in the second direction (the y-axis direction) may be connected to each other through a first connector BE1 (see FIG. 4), and the sensing electrodes RE adjacent to each other in the first direction (the x-axis direction) may be connected to each other through a second connector BE2 (see FIG. 4).

The dummy patterns DE may be electrically separated from the driving electrodes TE and the sensing electrodes RE. The driving electrodes TE, the sensing electrodes RE, and the dummy patterns DE may be arranged apart from one another. Each of the dummy patterns DE may be surrounded by the driving electrodes TE or the sensing electrodes RE. Each of the dummy patterns DE may be electrically floated.

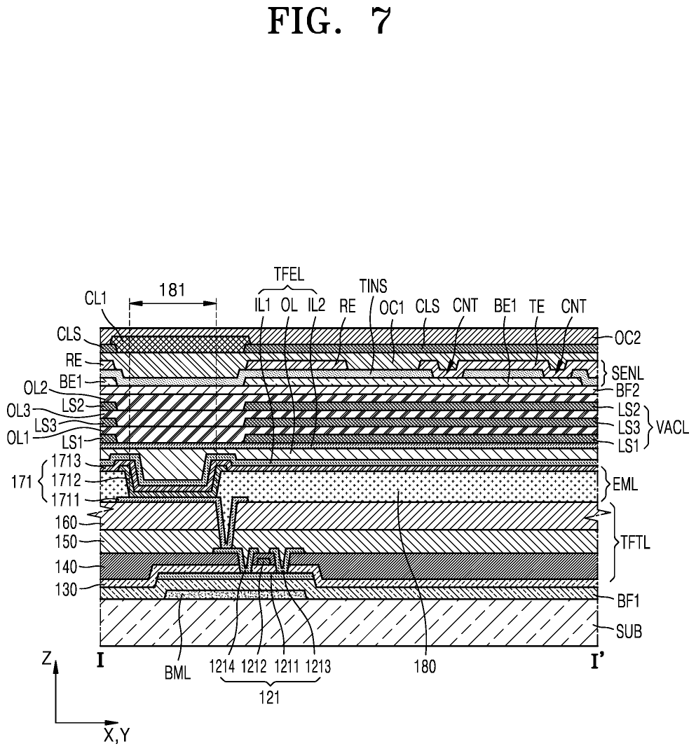

Due to the dummy patterns DE, a parasitic capacitance between a first opposite electrode 1713 (see FIG. 7) of the display element described below and the driving electrode TE, or a parasitic capacitance between the first opposite electrode 1713 and the sensing electrode RE may be reduced. In the case where the parasitic capacitance is reduced, a charging speed at which a mutual capacitance between the driving electrode TE and the sensing electrode RE is charged may be increased. However, due to the presence of the dummy patterns DE, the areas of the driving electrodes TE and the sensing electrodes RE are reduced, and accordingly, a mutual capacitance between the driving electrode TE and the sensing electrode RE may be reduced, and as a result, a voltage charged in the mutual capacitance may be easily influenced by noise. Accordingly, it is desirable that the area of the dummy patterns DE is properly set by taking into account a parasitic capacitance and a mutual capacitance.

The sensor lines TL1, TL2, and RL may be arranged in the sensor peripheral area TPA. The sensor lines TL1, TL2, and RL may include sensing lines RL connected to the sensing electrodes RE, and first driving lines TL1 and second driving lines TL2 connected to the driving electrodes TE.

The sensing electrodes RE arranged on one side of the sensor area TSA may be connected to the sensing lines RL. As an example, as shown in FIG. 3, a sensing electrode arranged on the right end among the sensing electrodes RE electrically connected in the first direction (the x-axis direction) may be connected to the sensing line RL. The sensing line RL may be connected to second sensor pads inside the second sensor pad area TPA2. Accordingly, the sensor driver 330 may be electrically connected to the sensing electrodes RE.

The driving electrodes TE arranged on one side of the sensor area TSA may be connected to the first driving lines TL1, and the driving electrodes TE arranged on another side of the sensor area TSA may be connected to the second driving lines TL2. As an example, as shown in FIG. 3, the driving electrode TE arranged at the lower end (the −y direction) among the driving electrodes TE electrically connected in the second direction (the y-axis direction) may be connected to the first driving line TL1, and the driving electrode TE arranged at the right end (the +y direction) may be connected to the second driving line TL2. The second driving lines TL2 may be connected to the driving electrodes TE on the upper side of the sensor area TSA through the left outer side of the sensor area TSA. The first driving lines TL1 and the second driving lines TL2 may be connected to the first sensor pads inside the first sensor pad area TPA1. Accordingly, the sensor driver 330 may be electrically connected to the driving electrodes TE.

A first guard line GL1 may be disposed outside a sensing line RL arranged in the outermost portion among the sensing lines RL. In addition, a first ground line GRL1 may be disposed outside the first guard line GL1. As shown in FIG. 3, the first guard line GL1 may be arranged on the right side of the sensing line RL arranged on the right end among the sensing lines RL, and the first ground line GRL1 may be arranged on the right side of the first guard line GL1.

The second guard line GL2 may be disposed between a sensing line RL arranged in the innermost portion among the sensing lines RL, and the first driving line TL1 arranged at the right end among the first driving lines TL1. As shown in FIG. 3, the sensing line RL arranged in the innermost portion among the sensing lines RL may be a sensing line RL arranged at the left end among the sensing lines RL. In addition, the second guard line GL2 may be disposed between the first driving line TL1 arranged at the right end among the first driving lines TL1, and the second ground line GRL2.

The third guard line GL3 may be disposed between the sensing line RL arranged in the innermost portion among the sensing lines RL, and the second ground line GRL2. The second ground line GRL2 may be connected to the first sensor pad arranged on the rightmost side among the first sensor pads inside the first sensor pad area TPA1, and the second sensor pad arranged on the leftmost side among the second sensor pads inside the second sensor pad area TPA2.

The fourth guard line GL4 may be disposed outside the second driving line TL2 arranged in the outermost portion among the second driving lines TL2. As shown in FIG. 3, the fourth guard line GL4 may be disposed on the left of the second driving line TL2 arranged at the left end among the second driving lines TL2. The third ground line CRL3 may be disposed outside the fourth guard line GL4. As shown in FIG. 3, the fourth guard line GL4 may be disposed on the left side and the upper side of the second driving lines TL2 arranged on the left side and the upper side among the second driving lines TL2. The third ground line GRL3 may be disposed on the left side and the upper side of the fourth guard line GL4.

The fifth guard line GL5 may be disposed inside the second driving line TL2 arranged in the innermost portion among the second driving lines TL2. As shown in FIG. 3, the fifth guard line GL5 may be disposed between the second driving line TL2 arranged at the right end among the second driving lines TL2, and the sensing electrodes RE.

A ground voltage may be applied to the first ground line GRL1, the second ground line CRL2, and the third ground line GRL3. In addition, a ground voltage may be applied to the first guard line GL1, the second guard line GL2, the third guard line GL3, the fourth guard line GL4, and the fifth guard line GL5.

As shown in FIG. 3, the driving electrodes TE adjacent to each other in the second direction (the y-axis direction) are electrically connected to each other, and the driving electrodes TE adjacent to each other in first direction (the x-axis direction) are electrically insulated from each other. In addition, the sensing electrodes RE adjacent to each other in first direction (the x-axis direction) are electrically connected to each other, and the sensing electrodes RE adjacent to each other in second direction (the y-axis direction) are electrically insulated from each other. Accordingly, a mutual capacitance may be formed at intersection points of the driving electrodes TE and the sensing electrodes RE.

In addition, as shown in FIG. 3, because the first guard line GL1 is disposed between the sensing line RL arranged in the outermost portion, and the first ground line GRL1, the sensing line RL arranged in the outermost portion may be reduced from being influenced by a voltage change of the first ground line GRL1. The second guard line GL2 is disposed between the sensing line RL arranged in the innermost portion and the first driving line TL1 arranged in the outermost portion. Accordingly, the sensing line RL arranged in the innermost portion and the first driving line TL1 arranged in the outermost portion may be reduced from being influenced by a voltage change of the first driving line TL1. Because the third guard line GL3 is disposed between the sensing line RL arranged in the innermost portion, and the second ground line GRL2, the sensing line RL arranged in the innermost portion may be reduced from being influenced by a voltage change of the second ground line GRL2. Because the fourth guard line GL4 is disposed between the second driving line TL2 arranged in the outermost portion, and the third ground line GRL3, the second driving line TL2 may be reduced from being influenced by a voltage change of the third ground line GRL3. Because the fifth guard line GL5 is disposed between the second driving line TL2 arranged in the innermost portion and the sensor electrodes TE and RE, the second driving line TL2 arranged in the innermost portion and the sensor electrodes TE and RE may be reduced from being influenced by each other.

FIG. 4 is a view showing an example of a sensor driver connected to the sensor electrodes. For convenience of description, FIG. 4 shows only the driving electrodes TE arranged on one column and electrically connected to each other in the second direction (the y-axis direction), and the sensing electrodes RE arranged on one row and electrically connected to each other in the first direction (the x-axis direction).

As shown in FIG. 4, the sensor driver 330 may include a driving signal output unit 331, a first sensor detector 332, and a first analog-to-digital converter 333.

The driving signal output unit 331 may output a touch driving signal TD to the driving electrodes TE through the first driving line TL1, and output a touch driving signal TD to the driving electrodes TE through the second driving line TL2. A touch driving signal TD may include a plurality of pulses each having an amplitude of VD. The driving signal output unit 331 may output touch driving signals TD to the driving lines TL1 and TL2 in a preset order. As an example, the driving signal output unit 331 may sequentially output touch driving signals TD from the driving electrodes TE arranged on the left of the touch sensor area TSA of FIG. 4 to the driving electrodes TE arranged on the right of the touch sensor area TSA.

The first sensor detector 332 senses a voltage charged in a first mutual capacitance Cm1 through the sensing line RL electrically connected to the sensing electrodes RE. As shown in FIG. 4, the first mutual capacitance Cm1 may be formed between the driving electrode TE and the sensing electrode RE.

The first sensor detector 332 may include a first operational amplifier OP1, a first feedback capacitor Cfb1, and a first reset switch RSW1. The first operational amplifier OP1 may include a first input terminal (−), a second input terminal (+), and an output terminal (out). The first input terminal (−) of the first operational amplifier OP1 may be connected to the sensing line RL, an initialization voltage VREF may be supplied to the second input terminal (+), and the output terminal (out) may be connected to a first storage capacitor. The first storage capacitor is connected between the output terminal (out) of the first operational amplifier OP1 and the ground, and configured to store an output voltage Vout1 of the first operational amplifier OP1. The first feedback capacitor Cfb1 and the first reset switch RSW1 may be connected in parallel between the first input terminal (−) and the output terminal (out) of the first operational amplifier OP1. The first reset switch RSW1 is configured to control connection of two opposite ends of the first feedback capacitor Cfb1. In the case where the first reset switch RSW1 is turned on and the two opposite ends of the first feedback capacitor Cfb1 are connected to each other, the first feedback capacitor Cfb1 may be reset.

An output voltage Vout1 of the first operational amplifier OP1 may be defined as Vout1=(Cm1×Vt1)/Cfb1. Here, “Cfb1” denotes a capacitance of the feedback capacitor Cfb1, “Vt1” denotes a voltage charged in the first mutual capacitance Cm1.

The first analog-to-digital converter 333 may convert the output voltage Vout1 stored in the first storage capacitor into first digital data, and output the first digital data.

As shown in FIG. 4, the sensor electrode layer SENL may determine whether a user is touched by sensing voltages charged in the first mutual capacitances Cm1.

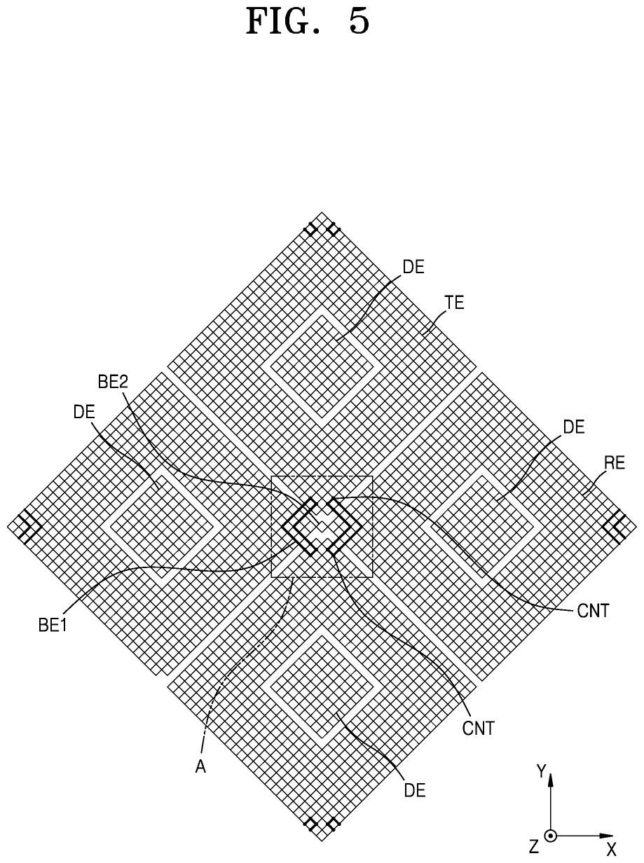

FIG. 5 is a detailed enlarged plan view of the sensor area which is a portion of FIG. 4. For convenience of description, FIG. 5 shows only two sensing electrodes RE adjacent to each other in the first direction (the x-axis direction), and two driving electrodes TE adjacent to each other in the second direction (the y-axis direction).

Referring to FIG. 5, though each of the driving electrodes TE, the sensing electrodes RE, and the dummy patterns DE may have a quadrangular shape in a plan view, the embodiment is not limited thereto. In addition, the driving electrodes TE, the sensing electrodes RE, the dummy patterns DE, the first connectors BE1, and the second connectors BE2 may have a mesh structure in a plan view. As used herein, the “plan view” means a view in a direction (the z-axis direction) perpendicular to the substrate SUB.

The sensing electrodes RE may be arranged in the first direction (the x-axis direction) and electrically connected to each other. The driving electrodes TE may be arranged in the second direction (the y-axis direction) and electrically connected to each other. The dummy patterns DE may be surrounded by the driving electrodes TE or the sensing electrodes RE. The driving electrodes TE, the sensing electrodes RE, and the dummy patterns DE may be electrically separated from one another. The driving electrodes TE, the sensing electrodes RE, and the dummy patterns DE may be arranged apart from one another.

For the sensing electrodes RE to be electrically separated from the driving electrodes TE in intersection regions thereof, the driving electrodes TE adjacent to each other in the second direction (the y-axis direction) may be connected to each other through the first connector BE1, and the sensing electrodes RE adjacent to each other in the first direction (the x-axis direction) may be connected to each other through the second connector BE2. The first connector BE1 may be disposed on a layer different from a layer on which the driving electrodes TE is disposed, and may be connected to the driving electrodes TE through first contact holes CNT1. As an example, the first connector BE1 may be disposed on a second buffer layer BF2 (see FIG. 7), and the driving electrodes TE may be disposed on a sensor insulating layer TINS (see FIG. 7).

The first connector BE1 may have a shape bent at least once. Though it is shown in FIG. 5 that the first connectors BE1 have a bent shape such as a bracket shape (“<” or “>”), the shape of the first connectors BE1 is not limited thereto. In addition, the driving electrodes TE adjacent to each other in the second direction (the y-axis direction) may be connected by the plurality of first connectors BE1, even when one of the first connectors BE1 is disconnected, the driving electrodes TE adjacent to each other in the second direction (the y-axis direction) may be stably connected to each other. Though it is shown in FIG. 5 that the driving electrodes TE adjacent to each other are connected to each other by two first connectors BE1, the number of first connectors BE1 is not limited thereto.

The second connector BE2 may be disposed on the same layer as that of the sensing electrodes RE, and may have a shape extending from the sensing electrodes RE. That is, the sensing electrodes RE and the second connector BE2 may be formed as one body. Accordingly, the sensing electrodes RE and the second connector BE2 may be simultaneously formed during a manufacturing process, and may include the same material. The sensing electrodes RE and the second connector BE2 may be disposed on the sensor insulating layer TINS.

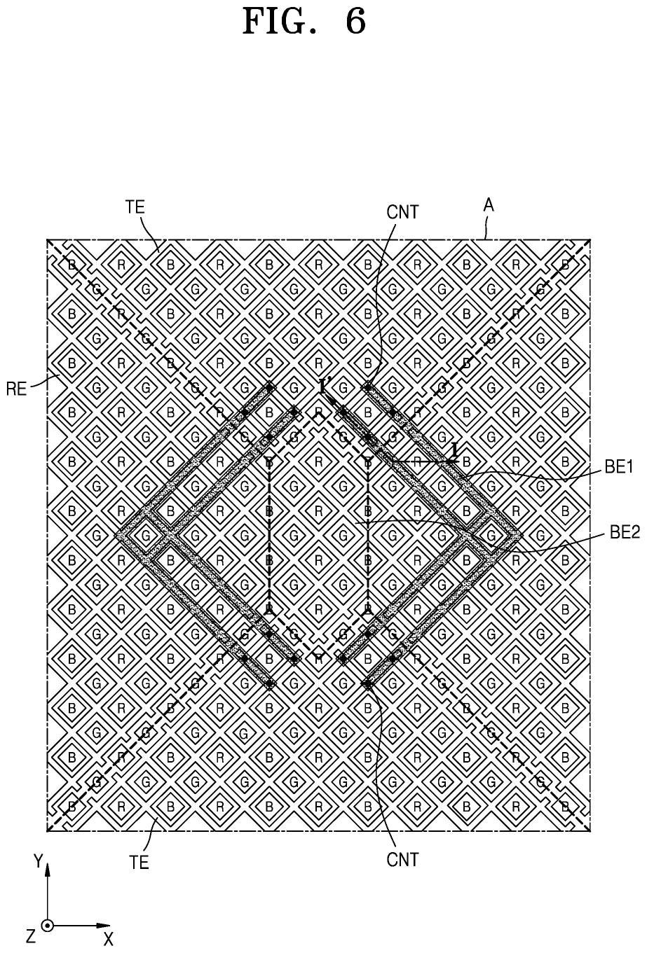

As shown in FIG. 7, which is a schematic cross-sectional view of the display module, taken along line I-I of FIG. 6, the first connectors BE1 connecting the driving electrodes TE adjacent to each other in the second direction (the y-axis direction) may be disposed on the second buffer layer BF2, and the driving electrode TE, the sensing electrodes RE, the dummy patterns DE, and the second connector BE2 may be disposed on the sensor insulating layer TINS. Accordingly, the driving electrodes TE may be electrically separated from the sensing electrodes RE in intersection regions thereof, and the sensing electrodes RE may be electrically connected to each other in the first direction (the x-axis direction), and the driving electrodes TE may be electrically connected to each other in the second direction (the y-axis direction).

FIG. 6 is a detailed enlarged plan view of the sensor electrodes and the connectors of FIG. 5, and is an enlarged view of a region A of FIG. 5.

As shown in FIG. 6, the driving electrodes TE, the sensing electrodes RE, the first connectors BE1, and the second connectors BE2 may each have a mesh structure in a plan view. The dummy patterns DE may also have a mesh structure in a plan view.

Because the driving electrodes TE, the sensing electrodes RE, the dummy patterns DE, and the second connectors BE2 are disposed on the same layer, they may be arranged apart from one another. There may be gaps between the driving electrode TE and the sensing electrode RE, between the driving electrode TE and the second connector BE2, between the driving electrode TE and the dummy pattern DE, and between the sensing electrode RE and the dummy pattern DE. For convenience of description, it is shown in FIG. 6 that a boundary between the driving electrode TE and the sensing electrode RE, a boundary between the driving electrode TE and the second connector BE2, and a boundary between the sensing electrode RE and the second connector BE2 are dashed lines.

The first connector BE1 may be connected to the driving electrode TE through a contact hole CNT. One end of the first connector BE1 may be connected to one of the driving electrodes TE adjacent to each other in the second direction (the y-axis direction) through a contact hole CNT. Another end of the first connector BE1 may be connected to another of the driving electrodes TE adjacent to each other in the second direction (the y-axis direction) through a contact hole CNT. The first connector BE1 may overlap the driving electrodes TE and the sensing electrodes RE. Alternatively, the first connector BE1 may overlap the second connector BE2 instead of the sensing electrode RE in a plan view. Alternatively, the first connector BE1 may overlap both the sensing electrode RE and the second connector BE2 in a plan view. Because the first connector BE1 is disposed on a layer different from a layer on which the driving electrodes TE, the sensing electrodes RE, and the second connector BE2 are disposed, even though the first connector BE1 overlaps the sensing electrodes RE, and/or the second connector BE2 in a plan view, the first connector BE1 may not be short-circuited to the sensing electrodes RE, and/or the second connector BE2.

The second connector BE2 may be disposed between the sensing electrodes RE. The second connector BE2 may be disposed on the same layer as the sensing electrodes RE and may extend from each of the sensing electrodes RE. Accordingly, the second connector BE2 may be connected to the sensing electrodes RE without a separate contact hole. That is, the sensing electrodes RE and the second connector BE2 may be formed as one body.

The pixels R, G, and B may include a first pixel R emitting light of a first color, a second pixel G emitting light of a second color, and a third pixel B emitting light of a third color. The first color may be, for example, red, the second color may be, for example, green, and the third color may be, for example, blue. Though it is shown in FIG. 6 that the first pixel R, the second pixel G, and the third pixel B each have a quadrangular planar shape in a plan view, the embodiment is not limited thereto. As an example, the first pixel R, the second pixel G, and the third pixel B may have planar shapes of other polygons, circles, or ellipses other than quadrangles in another embodiment. In addition, it is shown in FIG. 6 that the size of the third pixel B is the largest and the size of the second pixel G is the smallest. However, the embodiment is not limited thereto.

As described above, the driving electrodes TE, the sensing electrodes RE, the dummy patterns DE, the first connectors BE1, and the second connectors BE2 may have a mesh structure in a plan view. Accordingly, the pixels R, G, and B may not overlap the driving electrodes TE, the sensing electrodes RE, the dummy patterns DE, the first connectors BE1, and/or the second connectors BE2 in a plan view. As a result, light from the pixels R, G, and B may be prevented from being shielded by the driving electrodes TE, the sensing electrodes RE, the dummy patterns DE, the first connectors BE1, and/or the second connectors BE2, and thus, reduction in the brightness of the light may be prevented.

FIG. 7 is a schematic cross-sectional view of the display module, taken along line I-I′ of FIG. 6. As described above with reference to FIG. 2, the display panel 300 may include the substrate SUB, the display layer DISL, the sensor electrode layer SENL, and the color filter layer CL. As shown in FIG. 7, the display layer DISL disposed on the substrate SUB may include a first buffer layer BF1, a thin-film transistor layer TFTL, a light-emitting element layer EML, an encapsulation layer TFEL, and a viewing angle controlling layer VACL.

The first buffer layer BF1 disposed on one side of the substrate SUB may protect thin-film transistors 120 and the light-emitting element layer EML from moisture and the like penetrating through the substrate SUB. The first buffer layer BF1 may have a single-layered structure or a multi-layered structure. As an example, the first buffer layer BF1 may have a multi-layered structure in which one or more inorganic layers of a silicon nitride layer, a silicon oxynitride layer, a silicon oxide layer, a titanium oxide layer, and an aluminum oxide layer are alternately stacked. Depending on the case, the first buffer layer BF1 may be omitted.

The thin-film transistor layer TFTL disposed on the first buffer layer BF1 may include a first thin-film transistor 121, a gate insulating layer 130, an interlayer-insulating layer 140, a first planarization layer 150, and a second planarization layer 160.

The first thin-film transistor 121 may include a first active layer 1211, a first gate electrode 1212, a first source electrode 1213, and a first drain electrode 1214. Though FIG. 7 shows a top-gate type thin-film transistor in which the first gate electrode 1212 is disposed on the first active layer 1211, the embodiment is not limited thereto. That is, the first thin-film transistor 121 may be a bottom-gate type thin-film transistor in which the first gate electrode 1212 is disposed under the first active layer 1211, or a double-gate type thin-film transistor in which the first gate electrodes 1212 are disposed both on and under the first active layer 1211, respectively, in another embodiment.

The first active layer 1211 may be disposed on the first buffer layer BF1. The first active layer 1211 may include polycrystalline silicon, a single crystalline silicon, a low-temperature polycrystalline silicon, amorphous silicon, or an oxide semiconductor. As an example, the oxide semiconductor layer may include a two-component-based compound ABₓ, a three-component-based compound ABₓC_{y}, or a four-component-based compound ABₓC_{y}D_{z} including indium, zinc, gallium, tin, titanium, aluminum, hafnium (Hf), zirconium (Zr), or magnesium (Mg. Alternatively, the first active layer 1211 may include an oxide including indium, tin, and zinc (“ITZO”), or an oxide including indium, gallium, and tin (“IGZO”). A lower metal layer BML may be disposed below the first active layer 1211. The lower metal layer BML may have a single-layered structure or a multi-layered structure including one of molybdenum (Mo), aluminum (Al), chromium (Cr), gold (Au), titanium (Ti), nickel (Ni), neodymium (Nd) and copper (Cu), or an alloy thereof.

The gate insulating layer 130 may be disposed on the first active layer 1211. The gate insulating layer 130 may include an inorganic layer including silicon nitride, silicon oxynitride, silicon oxide, titanium oxide, or aluminum oxide.

The first gate electrode 1212 and a gate line may be disposed on the gate insulating layer 130. The first gate electrode 1212 may overlap the first active layer 1211 in a plan view. The first gate electrode 1212 and the gate line may have a single-layered structure or a multi-layered structure including one of molybdenum (Mo), aluminum (Al), chromium (Cr), gold (Au), titanium (Ti), nickel (Ni), neodymium (Nd) and copper (Cu), or an alloy thereof. As an example, the first gate electrode 1212 may have a structure of Mo/Al/Mo.

The interlayer-insulating layer 140 may be disposed on the first gate electrode 1212 and the gate line. The interlayer-insulating layer 140 may include an inorganic layer including silicon nitride, silicon oxynitride, silicon oxide, titanium oxide, or aluminum oxide.

The source electrode 1213, and the first drain electrode 1214 may be disposed on the interlayer-insulating layer 140. Each of the first source electrode 1213 and the first drain electrode 1214 may contact the first active layer 1211 through a contact hole passing through the interlayer-insulating layer 140. The first source electrode 1213 and the first drain electrode 1214 may have a single-layered structure or a multi-layered structure including one of molybdenum (Mo), aluminum (Al), chromium (Cr), gold (Au), titanium (Ti), nickel (Ni), neodymium (Nd) and copper (Cu), or an alloy thereof. As an example, each of the first source electrode 1213 and the first drain electrode 1214 may have a structure of Ti/Al/Ti.

In addition, the first thin-film transistor 121 always includes both the first source electrode 1213 and the first drain electrode 1214. As an example, in the case where a source region of the first active layer 1211 is directly connected to a drain region of an active layer of another thin-film transistor, the first thin-film transistor 121 may not include the first source electrode 1213. However, various modifications may be made. Alternatively, the first source electrode 1213 may be a portion of another conductive layer which is another line.

The first planarization layer 150 may be disposed on the first source electrode 1213 and the first drain electrode 1214 to planarize a step difference due to the first thin-film transistor 121. The first planarization layer 150 may include an insulating organic material such as acrylic resin, epoxy resin, phenolic resin, polyamide resin or polyimide resin.

The second planarization layer 160 may be disposed on the first planarization layer 150. The second planarization layer 160 may include an insulating organic material such as acrylic resin, epoxy resin, phenolic resin, polyamide resin or polyimide resin. In addition, various wirings may be disposed between the first planarization layer 150 and the second planarization layer 160.

The light-emitting element layer EML is disposed on the thin-film transistor layer TFTL. The light-emitting element layer EML may include a first display element 171 and a pixel-defining layer 180. The first display element 171 and the pixel-defining layer 180 may be disposed on the second planarization layer 160.

The first display element 171 may be an organic light-emitting element as shown in FIG. 7. In this case, the first display element 171 may include a first pixel electrode 1711, a first intermediate layer 1712, and a first opposite electrode 1713, wherein the first intermediate layer 1712 includes a first emission layer.

The first pixel electrode 1711 may be disposed on the second planarization layer 160. Though it is shown in FIG. 7 that the first pixel electrode 1711 is connected to the first drain electrode 1214 of the first thin-film transistor 121 through a contact hole passing through the first planarization layer 150 and the second planarization layer 160, the embodiment is not limited thereto. As an example, an intermediate conductive layer is disposed between the first planarization layer 150 and the second planarization layer 160 in another embodiment. The intermediate conductive layer may be connected to the first drain electrode 1214 of the first thin-film transistor 121 through a contact hole passing through the first planarization layer 150, and the first pixel electrode 1711 may be connected to the intermediate conductive layer through a contact hole passing through the second planarization layer 160. In addition, the first pixel electrode 1711 may be electrically connected to the first source electrode 1213 instead of the first drain electrode 1214.

Because the display panel 300 is a top-emission display panel configured to emit light through the first opposite electrode 1713 with respect to the first intermediate layer 1712 including the first emission layer, the first pixel electrode 1711 may include a layer including a metal material having a high reflectivity such as a stack structure of Ti/Al/Ti including aluminum and titanium, a stack structure of ITO/Al/ITO including aluminum and ITO, an APC alloy, and a stack structure of ITO/APC/ITO including an APC alloy and ITO. An APC alloy is an alloy including silver (Ag), palladium (Pd) and/or copper (Cu).

The pixel-defining layer 180 may define a first opening 181 exposing the central portion of the first pixel electrode 1711 and cover the edges of each first pixel electrode 1711. The pixel-defining layer 180 may include an organic material such as acrylic resin, epoxy resin, phenolic resin, polyamide resin, and polyimide resin.

The first intermediate layer 1712 including the first emission layer is disposed on the first pixel electrode 1711 and the pixel-defining layer 180. The first intermediate layer 1712 may include a hole transport layer or an electron transport layer in addition to the first emission layer. The first emission layer of the first intermediate layer 1712 may have a shape patterned to correspond to the first pixel electrode 1711 as shown in FIG. 7. The hole transport layer or the electron transport layer other than the first emission layer may be patterned to correspond to each first pixel electrode 1711 and may have a shape which is one body over other pixel electrodes including the first pixel electrode 1711. In addition, depending on the case, the first emission layer may also have a shape which is one body over the plurality of first pixel electrodes 1711. In this case, a quantum-dot layer and the like including quantum dots serving as a color-converting function may be disposed on a light path and may implement a full-color display.

The first opposite electrode 1713 is disposed on the first intermediate layer 1712 including the first emission layer. A capping layer may be formed on the first opposite electrode 1713. The first opposite electrode 1713 may include a transparent conductive material (“TCO”) such as ITO and IZO that may transmit light, or a semi-transmissive conductive material such as magnesium (Mg), silver (Ag) or an alloy of magnesium (Mg) and silver (Ag). The first opposite electrode 1713 may have a shape which is one body over the other pixel electrodes as well as the first pixel electrode 1711.

In an embodiment, the encapsulation layer TFEL is disposed on the light-emitting element layer EML, for example, the first opposite electrode 1713. The encapsulation layer TFEL may include an inorganic layer and an organic layer, and prevent oxygen or moisture from penetrating into the first intermediate layer including the first emission layer and the first opposite electrode 1713. As an example, the encapsulation layer TFEL may include a first inorganic layer IL1, an organic layer OL on the first inorganic layer IL1, and a second inorganic layer IL2 on the organic layer OL, wherein the first inorganic layer IL1 is disposed on the first opposite electrode 1713. The first inorganic layer IL1 and the second inorganic layer IL2 may each include an inorganic layer including silicon nitride, silicon oxynitride, silicon oxide, titanium oxide, or aluminum oxide. The organic layer OL may include acrylic resin, epoxy resin, phenolic resin, polyamide resin, or polyimide resin. The encapsulation layer TFEL may extend outside the display area and contact the first inorganic layer IL1 and the second inorganic layer IL2 outside the display area.

The viewing angle controlling layer VACL is disposed on the encapsulation layer TFEL. The viewing angle controlling layer VACL includes a first light-blocking layer LS1 and a second light-blocking layer LS2 over the first light-blocking layer LS1. In addition, as shown in FIG. 7, a third light-blocking layer LS3 may be further provided between the first light-blocking layer LS1 and the second light-blocking layer LS2. Hereinafter, the case where the viewing angle controlling layer VACL includes the third light-blocking layer LS3 as well as the first light-blocking layer LS1 and the second light-blocking layer LS2 is described.

Each of the first to third light-blocking layer LS1, LS2, and LS3 may include a black matrix material. Each of the first to third light-blocking layer LS1, LS2, and LS3 may include a metal oxide such as chrome oxide or a black resin. Each of the first to third light-blocking layer LS1, LS2, and LS3 may absorb most of light incident to a relevant layer. In addition, each of the first to third light-blocking layer LS1, LS2, and LS3 define an opening overlapping the first opening 181 of the pixel-defining layer 180 in a plan view. That is, each of the first to third light-blocking layer LS1, LS2, and LS3 may be disposed to correspond to between the display elements. In addition, the first to third light-blocking layer LS1, LS2, and LS3 may overlap each other in a plan view.

Light generated from the first intermediate layer 1712 including the first emission layer may progress in the front direction (the +z direction) which is the direction perpendicular to the substrate SUB of the display panel 300 and process in the first direction (the x-axis direction) and/or the second direction (the y-axis direction). As described above, light incident to the first to third light-blocking layers LS1, LS2, and LS3 does not progress in the front direction but is absorbed by the first to third light-blocking layers LS1, LS2, and LS3. Because the first to third light-blocking layers LS1, LS2, and LS3 are stacked in the front direction (the +z direction) which is perpendicular to the substrate SUB, in the case where light generated from the first intermediate layer 1712 including the first emission layer progresses in a direction of an angle deviating from a preset angle range from the direction (the z-axis direction) perpendicular to the substrate SUB, the light is incident to one of the first to third light-blocking layers LS1, LS2, and LS3, and thus, does not progress to the outside.

The viewing angle controlling layer VACL including the first to third light-blocking layers LS1, LS2, and LS3 may allow images displayed on the display panel 300 to be recognized within a specific viewing angle, and allow the relevant images not to be recognized when a viewing angle deviates from the specific viewing angle. For reference, as the number of stacked light-blocking layers of the viewing angle controlling layer VACL increases, a viewing angle within which images displayed on the display panel 300 are recognizable is reduced.

A first organic material layer OL1 covering the first light-blocking layer LS1 may be disposed between the first light-blocking layer LS1 and the third light-blocking layer LS3, a third organic material layer OL3 covering the third light-blocking layer LS3 may be disposed between the third light-blocking layer LS3 and the second light-blocking layer LS2, and a second organic material layer OL2 covering the second light-blocking layer LS2 may be disposed on the second light-blocking layer LS2. The first organic material layer OL1, the second organic material layer OL2, and/or the third organic material layer OL3 may include an insulating organic material such as acrylic resin, epoxy resin, phenolic resin, polyamide resin or polyimide resin.

The sensor electrode layer SENL may be disposed on the viewing angle controlling layer VACL. As shown in FIG. 7, the second buffer layer BF2 may be disposed between the viewing angle controlling layer VACL and the sensor electrode layer SENL. The second buffer layer BF2 may include an inorganic layer including silicon nitride, silicon oxynitride, silicon oxide, titanium oxide, or aluminum oxide.

As described above, the sensor electrode layer SENL may include the driving electrodes TE, the sensing electrodes RE, the dummy patterns DE, the first connectors BE1, the first driving lines TL1, the second driving lines TL2, the sensing lines RL, the guard lines GL1, GL2, GL3, GL4, and GL5, or the ground lines GRL1, GRL2, and GRL3, and the sensor insulating layer TINS. The electrodes of the sensor electrode layer SENL may overlap the second light-blocking layer LS2 of the viewing angle controlling layer VACL in a plan view. Accordingly, because light from the first display element 171 is reflected by the electrode of the sensor electrode layer SENL and is emitted to the outside through a plurality of times of reflections within the display panel 300, quality of images displayed may be effectively prevented from being deteriorated.

The first connectors BE1 may be disposed on the second buffer layer BF1. The first connectors BE1 may overlap the pixel-defining layer 180 in a plan view. The first connectors BE1 may have a stack structure of Ti/Al/Ti including aluminum and titanium, a stack structure of ITO/Al/ITO including aluminum and ITO, an APC alloy, and a stack structure of ITO/APC/ITO including an APC alloy and ITO. However, the embodiment is not limited thereto.

The sensor insulating layer TINS is disposed on the first connectors BE1. The sensor insulating layer TINS may include an inorganic layer including silicon nitride, silicon oxynitride, silicon oxide, titanium oxide, or aluminum oxide. Alternatively, the sensor insulating layer TINS may include an insulating organic material such as acrylic resin, epoxy resin, phenolic resin, polyamide resin or polyimide resin.

The driving electrodes TE, the sensing electrodes RE, the dummy patterns DE, the second connectors BE2, the first driving lines TL1, the second driving lines TL2, the sensing lines RL, the guard lines GL1, GL2, GL3, GL4, and GL5, and the ground lines GRL1, GRL2, and GRL3 may be disposed on the sensor insulating layer TINS. The driving electrodes TE, the sensing electrodes RE, the dummy patterns DE, and the second connectors BE2 may overlap the pixel-defining layer 180 in a plan view. The driving electrodes TE, the sensing electrodes RE, the dummy patterns DE, the second connectors BE2, the first driving lines TL1, the second driving lines TL2, the sensing lines RL, the guard lines GL1, GL2, GL3, GL4, and GL5, and the ground lines GRL1, GRL2, and CRL3 may have a stack structure of Ti/Al/Ti including aluminum and titanium, a stack structure of ITO/Al/ITO including aluminum and ITO, an APC alloy, and a stack structure of ITO/APC/ITO including an APC alloy and ITO. However, the embodiment is not limited thereto. The first driving lines TL1, the second driving lines TL2, and the sensing lines RL may be simultaneously formed while the driving electrodes TE and the sensing electrodes RE are formed, and may include the same material as that of the driving electrodes TE and the sensing electrodes RE in another embodiment.

The sensor insulating layer TINS may include a contact hole CNT passing through the sensor insulating layer TINS and exposing the first connectors BE1. The driving electrodes TE may be connected to the first connectors BE1 through the contact hole CNT.

As shown in FIG. 7, the first connectors BE1 connecting the driving electrodes TE adjacent to each other in the second direction (the y-axis direction) may be disposed on the second buffer layer BF2, and the driving electrodes TE, the sensing electrodes RE, and the second connector BE2 may be disposed on the sensor insulating layer TINS. Accordingly, the driving electrodes TE may be electrically separated from the sensing electrodes RE in intersection regions thereof, and the sensing electrodes RE may be electrically connected to each other in the first direction (the x-axis direction), and the driving electrodes TE may be electrically connected to each other in the second direction (the y-axis direction).

As described with reference to FIG. 3, the first driving lines TL1, the second driving lines TL2, and the sensing lines RL may extend to the sensor peripheral area TPA and be electrically connected to the first sensor pads inside the first sensor pad area TPA1 or the second sensor pads inside the second sensor pad area TPA2.

In an embodiment, the sensor electrode layer SENL may be covered by a first overcoat layer OC1. The first overcoat layer OC1 may include, for example, an insulating organic material such as acrylic resin, epoxy resin, phenolic resin, polyamide resin or polyimide resin.

The color filter layer CL may be disposed on the first overcoat layer OC1 to be disposed over the second light-blocking layer LS2. The color filter layer CL may include a first color filter CL1, a second color filter CL2, a third color filter CL3, and a color light-blocking layer CLS. It is shown in FIG. 7 that the first color filter CL1 is disposed to correspond to the first display element 171. The color light-blocking layer CLS may be arranged between the first color filter CL1, the second color filter CL2, and/or the third color filter CL3. In addition, the color light-blocking layer CLS may be also arranged between the first color filters CL1 and the second color filters CL2, and/or between the third color filters CL3.

The color light-blocking layer CLS may include a black matrix material. The color light-blocking layer CLS may include, for example, a metal oxide such as chrome oxide or a black resin. The color light-blocking layer CLS may absorb most of incident light. In addition, the color light-blocking layer CLS defines an opening that overlaps the first opening 181 of the pixel-defining layer 180. That is, when viewed in the direction (the z-axis direction) perpendicular to the substrate SUB (i.e., plan view), the first light-blocking layer LS1, the second light-blocking layer LS2, and the third light-blocking layer LS3 may be disposed inside the color light-blocking layer CLS. That is, the first light-blocking layer LS1, the second light-blocking layer LS2, and the third light-blocking layer LS3 may overlap the color light-blocking layer CLS, and a size of any of the first light-blocking layer LS1, the second light-blocking layer LS2, or the third light-blocking layer LS3 may be smaller than a size of the color light-blocking layer CLS in a plan view. As described above, the electrodes of the sensor electrode layer SENL may overlap the second light-blocking layer LS2 of the viewing angle controlling layer VACL in a plan view. Accordingly, the electrodes of the sensor electrode layer SENL may be disposed between the second light-blocking layer LS2 and the color light-blocking layer CLS. Through this, light directed to the display panel 300 from the outside may be effectively prevented from being reflected by the electrodes of the sensor electrode layer SENL.

The first color filter CL1 may overlap the first opening 181 of the pixel-defining layer 180 in a plan view. That is, the first color filter CL1 may fill an opening of the color light-blocking layer CLS corresponding to the first opening 181 of the pixel-defining layer 180. In addition, the first color filter CL1 may transmit light in a wavelength band to which light emitted from the first display element 171 belongs, and absorb light that is not in the wavelength band. Light emitted from the first display element 171 may have a wavelength in a range from about 570 nanometers (nm) to about 750 nm. The first color filter CL1 may selectively transmit light having a wavelength in a wavelength band of about 570 nm to about 750 nm.

The first color filter CL1 and the color light-blocking layer CLS may be covered by a second overcoat layer OC2. In an embodiment, the second overcoat layer OC2 may include, for example, an insulating organic material such as acrylic resin, epoxy resin, phenolic resin, polyamide resin or polyimide resin.

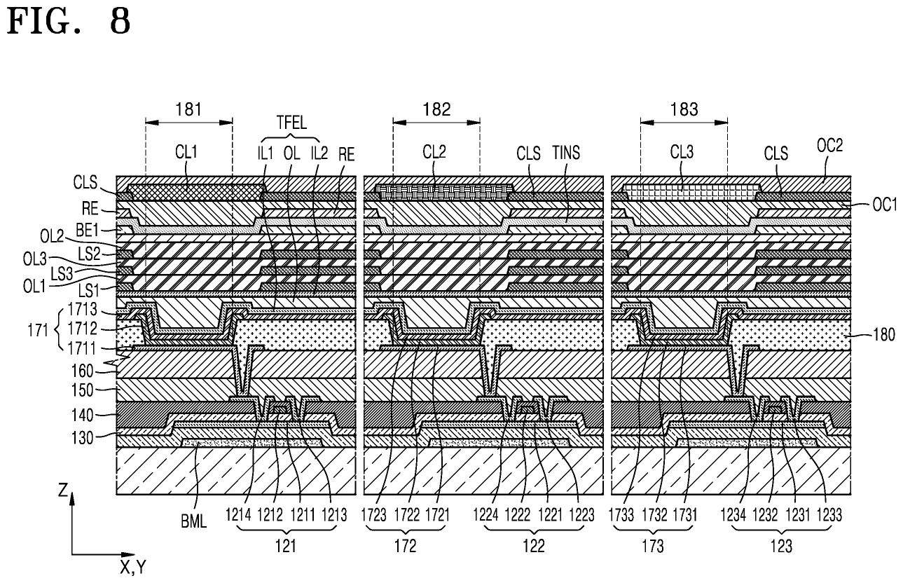

Because FIG. 7 shows portions in which the first thin-film transistor 121, the first display element 171, and the first color filter CL1 of the display panel 300 are disposed, as shown in FIG. 8, which is a schematic cross-sectional view of a portion of the display panel 300 according to an embodiment, the display panel 300 may include portions on which a second thin-film transistor 122, a second display element 172, and the second color filter CL2 are disposed, and portions on which a third thin-film transistor 123, a third display element 173, and the third color filter CL3 are disposed.

The second thin-film transistor 122 may include a second active layer 1221, a second gate electrode 1222, a second source electrode 1223, and a second drain electrode 1224. The third thin-film transistor 123 may include a third active layer 1231, a third gate electrode 1232, a third source electrode 1233, and a third drain electrode 1234. Because descriptions of the elements of the second thin-film transistor 122 and the elements of the third thin-film transistor 123 are the same as those of the elements of the first thin-film transistor 121, the descriptions thereof are omitted.

The second display element 172 may include a second pixel electrode 1721, a second intermediate layer 1722, and a second opposite electrode 1723, wherein the second intermediate layer 1722 includes a second emission layer. The third display element 173 may include a third pixel electrode 1731, a third intermediate layer 1732, and a third opposite electrode 1733, wherein the third intermediate layer 1732 includes a third emission layer. The first opposite electrode 1713, the second opposite electrode 1723, and the third opposite electrode 1733 may each be provided in one body. In layers of the first intermediate layer 1712 except the first emission layer, layers of the second intermediate layer 1722 except the second emission layer, and layers of the third intermediate layer 1732 except the third emission layer, layers corresponding to each other may be provided in one body. As an example, an electron transport layer of the first intermediate layer 1712, an electron transport layer of the second intermediate layer 1722, and an electron transport layer of the third intermediate layer 1732 may be provided in one body. Because descriptions of the second pixel electrode 1721 and the third pixel electrode 1731 are the same as that of the first pixel electrode 1711, the descriptions thereof are omitted.

Because the pixel-defining layer 180 defines the first opening 181 that exposes the first pixel electrode 1711 as described above, similarly, the pixel-defining layer 180 defines a second opening 182 exposing the second pixel electrode 1721 and a third opening 183 exposing the third pixel electrode 1731. The color light-blocking layer CLS defines openings that overlap the second opening 182 and the third opening 183 of the pixel-defining layer 180 in addition to the opening that overlaps the first opening 181 of the pixel-defining layer 180 in a plan view. As described above, the color filter layer CL defines the first color filter CL1 filling the opening of the color light-blocking layer CLS corresponding to the first opening 181 of the pixel-defining layer 180. Likewise, the color filter layer CL defines the second color filter CL2 filling the opening of the color light-blocking layer CLS corresponding to the second opening 182 of the pixel-defining layer 180, and defines the third color filter CL3 filling the opening of the color light-blocking layer CLS corresponding to the third opening 183 of the pixel-defining layer 180. Accordingly, like the first color filter CL1 is disposed to correspond to the first display element 171, the second color filter CL2 may be disposed to correspond to the second display element 172, and the third color filter CL3 may be disposed to correspond to the third display element 173.

The second color filter CL2 may transmit light in a wavelength band to which light emitted from the second display element 172 belongs, and absorb light that is not in the wavelength band. Light emitted from the second display element 172 may have a wavelength in a range from about 495 nm to about 570 nm. The second color filter CL2 may selectively transmit light having a wavelength in a wavelength band of about 495 nm to about 570 nm. The third color filter CL3 may transmit light in a wavelength band to which light emitted from the third display element 173 belongs, and absorb light that is not in the wavelength band. Light emitted from the third display element 173 may have a wavelength in a range from about 450 nm to about 495 nm. The third color filter CL3 may selectively transmit light having a wavelength in a wavelength band of about 450 nm to about 495 nm.

The display panel 300 according to the present embodiment reduces external light reflection by using the color filter layer CL and limits a range of a viewing angle within which images displayed on the display panel 300 are recognizable in the outside, by using the viewing angle controlling layer VACL. Accordingly, the display panel 300 in which high-quality images are displayed and privacy is protected, or usage convenience is remarkably increased, may be implemented.

As an example, in the case where the display panel is mounted in an automobile and used as a center information display (CID) for automobile, images displayed on the display panel may be reflected by a front windshield of a vehicle to hinder a driver's driving. However, in the case where the display panel 300 including the viewing angle controlling layer VACL according to the present embodiment is mounted in an automobile and used as a center information display (CID) for automobile, because a progression direction of light from the display element may be limited by the viewing angle controlling layer VACL, and light from the display element is not directed to a front glass of an automobile or the amount of light directed to the front glass may be reduced, images displayed on the display panel 300 may be effectively prevented from being reflected by the front glass of the vehicle.

In addition, unlike FIG. 7 or 8, the sensor electrode layer SENL including the driving electrodes TE and the sensing electrodes RE is directly disposed on the encapsulation layer TFEL, a distance between the first opposite electrode 1713 and the driving electrode TE of the sensor electrode layer SENL, or a distance between the first opposite electrode 1713 and the sensing electrode RE of the sensor electrode layer SENL is reduced. Accordingly, a parasitic capacitance occurring between the first opposite electrode 1713 and the driving electrode TE of the sensor electrode layer SENL, or between the first opposite electrode 1713 and the sensing electrode RE of the sensor electrode layer SENL may increase. In the case where a parasitic capacitance increases, a charging speed at which a mutual capacitance between the driving electrode TE and the sensing electrode RE is reduced, and thus, the sensor electrode layer SENL may not properly operate.

However, in the display panel 300 according to the present embodiment, the viewing angle controlling layer VACL is disposed between the sensor electrode layer SENL and the encapsulation layer TFEL. Accordingly, a distance between the first opposite electrode 1713 and the driving electrode TE of the sensor electrode layer SENL, and a distance between the first opposite electrode 1713 and the sensing electrode RE of the sensor electrode layer SENL may be increased. Accordingly, a parasitic capacitance occurring between the first opposite electrode 1713 and the driving electrode TE of the sensor electrode layer SENL, or between the first opposite electrode 1713 and the sensing electrode RE of the sensor electrode layer SENL may be remarkably reduced. In addition, in the display panel 300 according to the present embodiment, despite the presence of the viewing angle controlling layer VACL, a distance between the sensor electrode layer SENL and the cover window 100 is maintained short. Accordingly, a user's touch on the cover window 100 may be accurately recognized through the sensor electrode layer SENL.

In addition, in the display panel 300 according to the present embodiment, a process of forming the first light-blocking layer LS1, the second light-blocking layer LS2, and the third light-blocking layer LS3 may be similar to the process of forming the color light-blocking layer CLS. In addition, a process of forming the first organic material layer OL1, the second organic material layer OL2, and the third organic material layer OL3 may be similar to a process of forming the first overcoat layer OC1 and the second overcoat layer OC2. Accordingly, the display panel 300 according to the present embodiment may be manufactured without changing the process much.

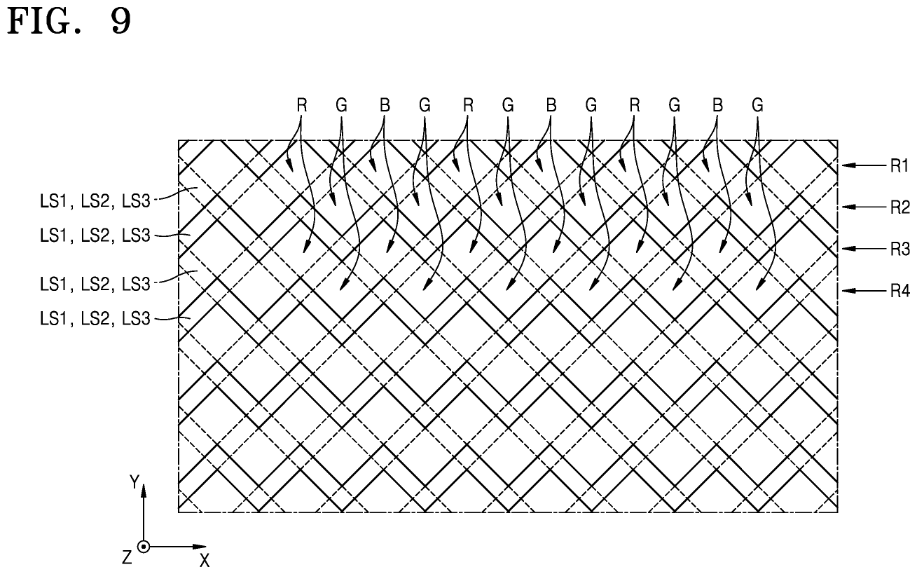

FIG. 9 is a schematic plan view of a portion of the display panel 300 according to an embodiment. It is shown in FIG. 9 that first pixels R emitting light of a first color and third pixels B emitting light of a third color are alternately arranged in the first direction on a first row R1 extending in the first direction (the x-axis direction), second pixels G emitting light of a second color are arranged on a second row R2 extending in the first direction, the first pixels R and the third pixels B are alternately arranged in the first direction on a third row R3 extending in the first direction, and the second pixels G are arranged on a fourth row R4 extending in the first direction. The first to fourth rows R1, R2, R3, and R4 may be sequentially arranged in the second direction (the y-axis direction) crossing the first direction. The configuration of the first to fourth rows R1, R2, R3, and R4 may repeatedly appear in the second direction.

In a plan view, the first light-blocking layer LS1 may be arranged between the first row R1 and the second row R2. That is, the first light-blocking layer LS1 may be disposed to correspond to between the display elements on the first row R1 and the second row R2. As shown in FIG. 9, the first light-blocking layer LS1 disposed between the first row R1 and the second row R2 may have a shape in which a “W” shape repeats in the first direction. For convenience of description, FIG. 9 shows the first light-blocking layer LS1 disposed between the first row R1 and the second row R2 by using dashed lines. In the aspect that the first light-blocking layer LS1 does not extend straightly in a first direction, but extends with the “W” shape in the first direction, it can be said that the first light-blocking layer LS1 extends “substantially” in a first direction.

The first light-blocking layer LS1 may be also disposed between the second row R2 and the third row R3. That is, the first light-blocking layer LS1 may be disposed to correspond to between the display elements on the second row R2 and the third row R3. As shown in FIG. 9, the first light-blocking layer LS1 disposed between the second row R2 and the third row R3 may have a shape in which a “W” shape repeats in the first direction. For convenience of description, FIG. 9 shows the first light-blocking layer LS1 disposed between the second row R2 and the third row R3 by using solid lines.

Likewise, as shown by dashed lines between the third row R3 and the fourth row R4, the first light-blocking layer LS1 may be disposed between the third row R3 and the fourth row R4. That is, the first light-blocking layer LS1 may be disposed to correspond to between the display elements on the third row R3 and the fourth row R4.

The first light-blocking layer LS1 disposed between the first row R1 and the second row R2, the first light-blocking layer LS1 disposed between the second row R2 and the third row R3, and the first light-blocking layer LS1 disposed between the third row R3 and the fourth row R4 may be connected to each other. That is, the first light-blocking layer LS1 disposed between the first row R1 and the second row R2, the first light-blocking layer LS1 disposed between the second row R2 and the third row R3, and the first light-blocking layer LS1 disposed between the third row R3 and the fourth row R4 may be one body.

In a plan view, the second light-blocking layer LS2 may have the same shape as that of the first light-blocking layer LS1 and be disposed to correspond to between the display elements. That is, the second light-blocking layers LS2 may overlap the first light-blocking layers LS1 in a plan view. Accordingly, the second light-blocking layer LS2 disposed between the first row R1 and the second row R2, the second light-blocking layer LS2 disposed between the second row R2 and the third row R3, and the second light-blocking layer LS2 disposed between the third row R3 and the fourth row R4 may be connected to each other. That is, the second light-blocking layer LS2 disposed between the first row R1 and the second row R2, the second light-blocking layer LS2 disposed between the second row R2 and the third row R3, and the second light-blocking layer LS2 disposed between the third row R3 and the fourth row R4 may be one body.

The third light-blocking layer LS3 disposed between the first light-blocking layer LS1 and the second light-blocking layer LS2 may have the same shape as that of the first light-blocking layer LS1 and be disposed to correspond to between the display elements when viewed in the direction (the z-axis direction) perpendicular to the substrate SUB (i.e., in a plan view). That is, the third light-blocking layers LS3 may overlap the first light-blocking layers LS1 in a plan view. Accordingly, the third light-blocking layer LS3 disposed between the first row R1 and the second row R2, the third light-blocking layer LS3 disposed between the second row R2 and the third row R3, and the third light-blocking layer LS3 disposed between the third row R3 and the fourth row R4 may be connected to each other. That is, the third light-blocking layer LS3 disposed between the first row R1 and the second row R2, the third light-blocking layer LS3 disposed between the second row R2 and the third row R3, and the third light-blocking layer LS3 disposed between the third row R3 and the fourth row R4 may be one body.

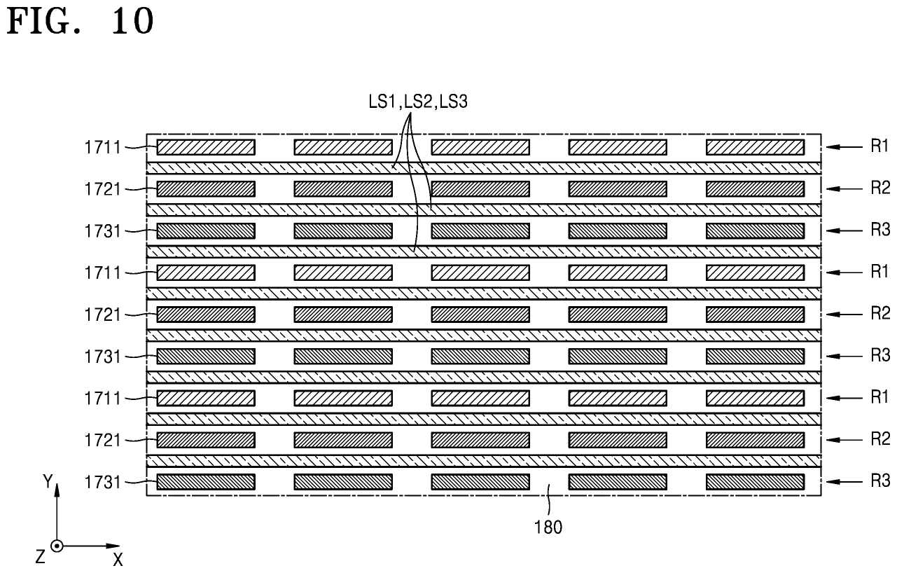

FIG. 10 is a schematic plan view of a portion of the display panel 300 according to an embodiment. FIG. 10 shows the first light-blocking layers LS1, the second light-blocking layers LS2 on the first light-blocking layers LS1, the third light-blocking layers LS3 disposed between the first light-blocking layers LS1 and the second light-blocking layers LS2, the first pixel electrodes 1711, the second pixel electrodes 1721, and the third pixel electrodes 1731.

As shown in FIG. 10, the plurality of first light-blocking layers LS1 may each extend in the first direction (the x-axis direction), and the plurality of first light-blocking layers LS1 may be arranged in the second direction (the y-axis direction) crossing the first direction. The plurality of second light-blocking layers LS2 may each extend in the first direction, and the plurality of second light-blocking layers LS2 may be arranged in the second direction crossing the first direction. Likewise, the plurality of third light-blocking layers LS3 may each extend in the first direction, and the plurality of third light-blocking layers LS3 may be arranged in the second direction crossing the first direction.

In this case, among the plurality of display elements, display elements arranged on one row extending in the first direction may emit light in a same wavelength band. It is shown in FIG. 10 that the first pixel electrode 1711 of the first display element 171 that may emit light in a red wavelength band is arranged on the first row R1, the second pixel electrode 1721 of the second display element 172 that may emit light in a green wavelength band is arranged on the second row R2, and the third pixel electrode 1731 of the third display element 173 that may emit light in a blue wavelength band is arranged on the third row R3. In addition, it is shown that the first row R1, the second row R2, and the third row R3 sequentially arranged are repeatedly positioned.

In the display panel 300 according to the present embodiment, a viewing angle in the second direction (the y-axis direction) may be limited by the first light-blocking layers LS1, the second light-blocking layers LS2, and the third light-blocking layers LS3 each extending in the first direction (the x-axis direction). Accordingly, in the case where the display panel 300 is mounted in an automobile and used as a center information display for automobile, because progression of light from the display element in the second direction (the y-axis direction) is limited, images displayed on the display panel 300 may be effectively prevented from being reflected by the front glass of the vehicle.

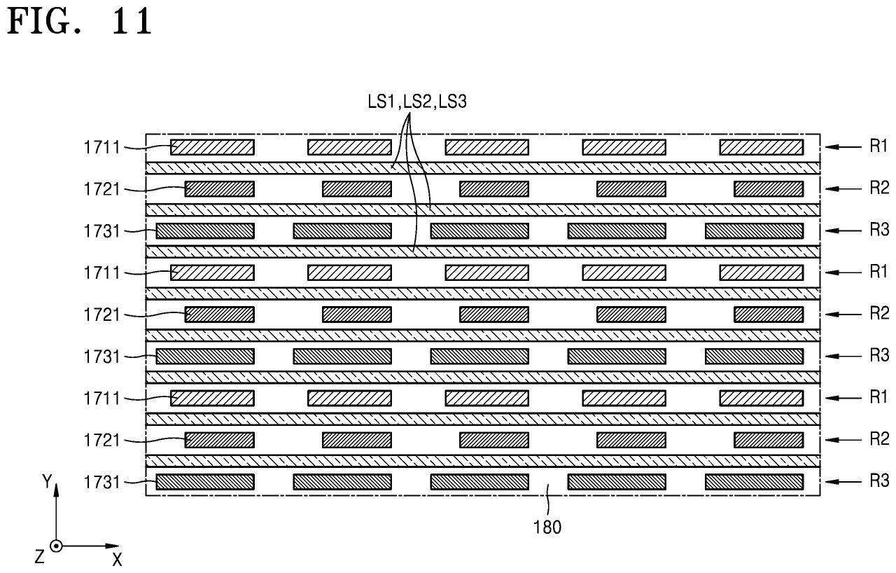

FIG. 11 is a schematic plan view of a portion of the display panel 300 according to an embodiment. In the display panel 300 according to the present embodiment, the width of a portion of the first pixel electrode 1711 not covered by the pixel-defining layer 180 in the second direction is constant, wherein the width may be a width of the first display elements 171 in the second direction (the y-axis direction). In addition, the width of a portion of the second pixel electrode 1721 not covered by the pixel-defining layer 180 in the second direction is also constant, wherein the width may be a width of the second display elements 172 in the second direction. The width of a portion of the third pixel electrode 1731 not covered by the pixel-defining layer 180 in the second direction is also constant, wherein the width may be a width of the third display elements 173 in the second direction. In addition, the widths of the first display element 171, the second display element 172, and the third display element 173 in the second direction are the same.

In this case, the length of a portion of the first pixel electrode 1711 not covered by the pixel-defining layer 180 in the first direction, wherein the length may be a first length of the first display elements 171 in the first direction arranged on the first row R1 extending in the first direction (the x-axis direction), the length of a portion of the second pixel electrode 1721 not covered by the pixel-defining layer 180 in the first direction, wherein the length may be a second length of the second display elements 172 in the first direction arranged on the second row R2 extending in the first direction, and the length of a portion of the third pixel electrode 1731 not covered by the pixel-defining layer 180 in the first direction, wherein the length may be a third length of the third display elements 173 in the first direction arranged on the third row R3 extending in the first direction are different from one another.

In the display elements, a light efficiency thereof may be different for each color. As an example, a light efficiency of the first display elements 171 emitting red light may be less than a light efficiency of the second display elements 172 emitting green light, and greater than a light efficiency of the third display elements 173 emitting blue light. Accordingly, an entire white balance may be maintained by making the area of the first display elements 171 greater than the area of the second display elements 172, and making the area of the first display elements 171 less than the area of the third display elements 173. For this purpose, the first length, the second length, and the third length may be made different from one another. Specifically, the first length may be made greater than the second length, and less than the third length.

For reference, the reason why the width of the first display elements 171, the width of the second display elements 172, and the width of the third display elements 173 are made same in the second direction (the y-axis direction), because the first light-blocking layers LS1 extending in the first direction are apart from each other in the second direction, the second light-blocking layers LS2 extending in the first direction are apart from each other in the second direction, and the third light-blocking layers LS3 extending in the first direction are apart from each other in the second direction, this is for a viewing angle limit in the second direction to be equally applied to the first display element 171, the second display element 172, and the third display element 173.

When the width of the first display elements 171, the width of the second display elements 172, and the width of the third display elements 173 are not the same in the second direction (the y-axis direction), a viewing angle in which light from the first display element 171 is limited in the second direction, a viewing angle in which light from the second display element 172 is limited in the second direction, and a viewing angle in which light from the third display element 173 is limited in the second direction may become different from one another, and thus, a white balance may become different depending on a viewing angle in the second direction.

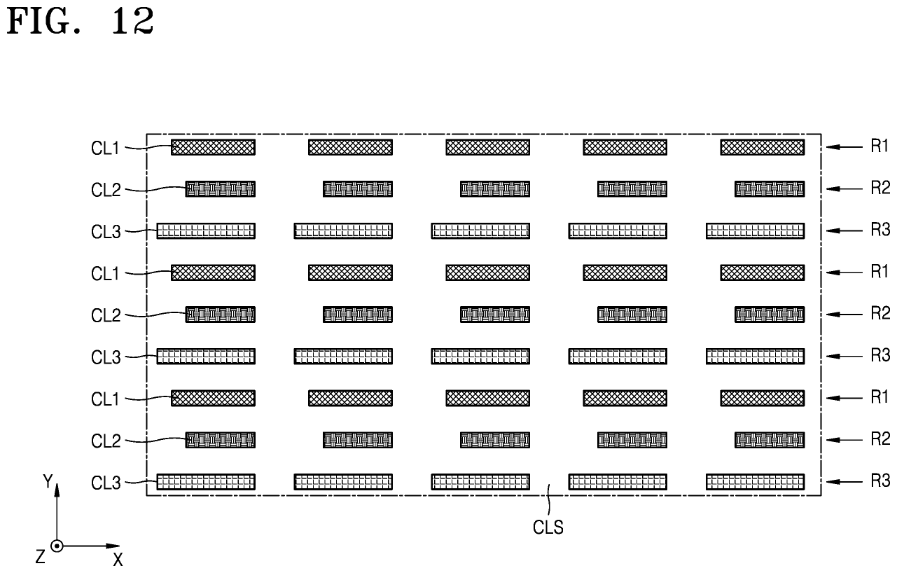

FIG. 12 is a schematic plan view of a portion of the display panel 300 according to an embodiment and shows the first color filters CL1, the second color filters CL2, the third color filters CL3, and the color light-blocking layer CLS. In the display panel 300 according to the present embodiment, the first length of the first color filters CL1 in the first direction arranged on the first row R1 extending in the first direction (the x-axis direction), the second length of the second color filters CL2 in the first direction arranged on the second row R2 extending in the first direction, and the third length of the third color filters CL3 in the first direction arranged on the third row R3 extending in the first direction are different from each other. The color light-blocking layer CLS is disposed between the first color filters CL1, the second color filters CL2, and the third color filters CL3.

As described above, light efficiencies of the display elements are different for each color. As an example, a light efficiency of the first display elements 171 emitting red light may be less than a light efficiency of the second display elements 172 emitting green light, and greater than a light efficiency of the third display elements 173 emitting blue light. Accordingly, an entire white balance may be maintained by making the area of the first color filters CL1 greater than the area of the second color filters CL2, and making the area of the first color filters CL1 less than the area of the third color filters CL3. For this purpose, the first length, the second length, and the third length may be made different from one another. Specifically, the first length may be made greater than the second length, and less than the third length. For reference, the width of the first color filter CL1, the width of the second color filter CL2, and the width of the third color filter CL3 in the second direction (the y-axis direction) may be made same.

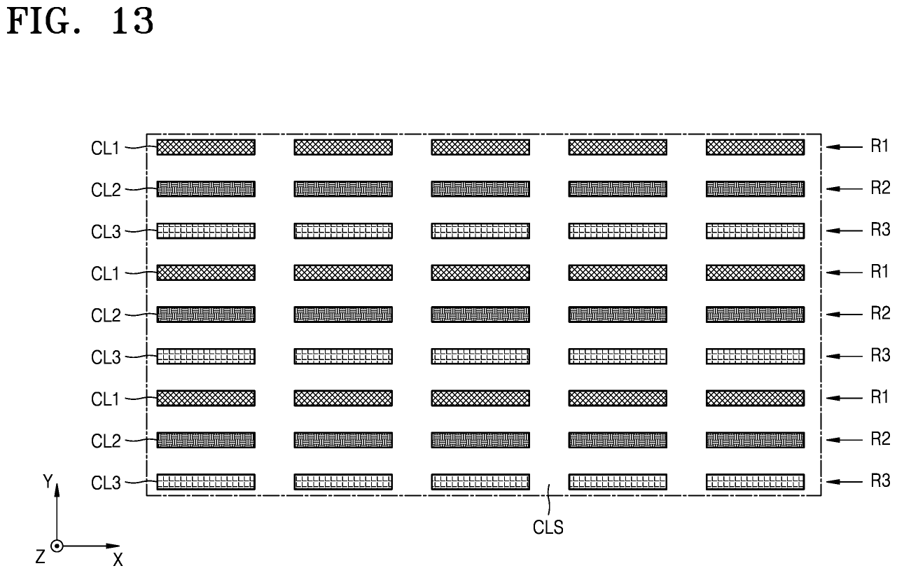

FIG. 13 is a schematic plan view of a portion of the display panel 300 according to an embodiment and shows the first color filters CL1, the second color filters CL2, the third color filters CL3, and the color light-blocking layer CLS. In the display panel 300 according to the present embodiment, the first length of the first color filters CL1 in the first direction arranged on the first row R1 extending in the first direction (the x-axis direction), the second length of the second color filters CL2 in the first direction arranged on the second row R2 extending in the first direction, and the third length of the third color filters CL3 in the first direction arranged on the third row R3 extending in the first direction are the same. Instead, the first color filters CL1 have a first transmittance, the second color filters CL2 have a second transmittance, the third color filters CL3 have a third transmittance, and the first transmittance, the second transmittance, and the third transmittance are different from one another.

As described above, light efficiencies of the display elements are different for each color. As an example, a light efficiency of the first display elements 171 emitting red light may be less than a light efficiency of the second display elements 172 emitting green light, and greater than a light efficiency of the third display elements 173 emitting blue light. Accordingly, an entire white balance may be maintained by making the first transmittance of the first color filters CL1 greater than the transmittance of the second color filters CL2, and making the transmittance of the first color filters CL1 less than the transmittance of the third color filters CL3. For reference, the width of the first color filter CL1, the width of the second color filter CL2, and the width of the third color filter CL3 in the second direction (the y-axis direction) may be made same.

According to an embodiment, the display panel with an increased user convenience, which may be easily manufactured may be implemented. However, the scope of the present disclosure is not limited by this effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display panel comprising:
a substrate;
a plurality of display elements disposed over the substrate;
a plurality of first light-blocking layers disposed over the plurality of display elements and corresponding to places between the plurality of display elements;
a plurality of second light-blocking layers disposed over the plurality of first light-blocking layers and corresponding to the places between the plurality of display elements; and
a color filter layer disposed over the plurality of second light-blocking layers and including color filters corresponding to the plurality of display elements.

2. The display panel of claim 1, wherein the plurality of first light-blocking layers are connected to each other, and the plurality of second light-blocking layers are connected to each other.

3. The display panel of claim 1, wherein each of the plurality of first light-blocking layers extend substantially in a first direction, and the plurality of first light-blocking layers are arranged in a second direction crossing the first direction, and
wherein each of the plurality of second light-blocking layers extends in the first direction, and the plurality of second light-blocking layers are arranged in the second direction.

4. The display panel of claim 3, wherein, among the plurality of display elements, each of display elements arranged on one row extending in the first direction emits light of a wavelength belonging to a same wavelength band.

5. The display panel of claim 3, wherein a width of each of the plurality of display elements in the second direction is the same.

6. The display panel of claim 5, wherein the plurality of display elements include first display elements arranged on a first row extending in the first direction, second display elements arranged on a second row extending in the first direction, and third display elements arranged on a third row extending in the first direction, and
wherein a first length of the first display elements in the first direction, a second length of the second display elements in the first direction, and a third length of the third display elements in the first direction are different from one another.

7. The display panel of claim 6, wherein the first display elements emit red light, the second display elements emit green light, and the third display elements emit blue light, and
wherein the first length is greater than the second length and less than the third length.

8. The display panel of claim 5, wherein the color filters include first color filters arranged on a first row extending in the first direction, second color filters arranged on a second row extending in the first direction, and third color filters arranged on a third row extending in the first direction, and wherein a first length of the first color filters in the first direction, a second length of the second color filters, and a third length of the third color filters in the first direction are different from one another.

9. The display panel of claim 8, wherein the first color filters transmit red light, the second color filters transmit green light, and the third color filters transmit blue light, and
wherein the first length is greater than the second length and less than the third length.

10. The display panel of claim 5, wherein the plurality of display elements include first display elements arranged on a first row extending in the first direction, second display elements arranged on a second row extending in the first direction, and third display elements arranged on a third row extending in the first direction, and
wherein a first length of the first display elements in the first direction, a second length of the second display elements in the first direction, and a third length of the third display elements in the first direction are the same.

11. The display panel of claim 10, wherein the color filters include first color filters arranged on the first row, second color filters arranged on the second row, and third color filters arranged on the third row, wherein the first color filters have a first transmittance, the second color filters have a second transmittance, and the third color filters have a third transmittance, and
wherein the first transmittance, the second transmittance, and the third transmittance are different from one another.

12. The display panel of claim 11, wherein the first color filters transmit red light, the second color filters transmit green light, and the third color filters transmit blue light, and
wherein the first transmittance is greater than the second transmittance and less than the third transmittance.

13. The display panel of claim 1, wherein in a plan view, the plurality of second light-blocking layers overlaps the plurality of first light-blocking layers.

14. The display panel of claim 1, wherein the color filter layer further includes a color light-blocking layer between the color filters.

15. The display panel of claim 14, wherein in a plan view, the plurality of first light-blocking layers is inside the color light-blocking layer, and the plurality of second light-blocking layers is inside the color light-blocking layer.

16. The display panel of claim 1, further comprising a sensor electrode layer disposed between the plurality of second light-blocking layers and the color filter layer.

17. The display panel of claim 16, wherein an electrode of the sensor electrode layer in a display area overlaps the plurality of second light-blocking layers in a plan view.

18. The display panel of claim 16, wherein the color filter layer further includes a color light-blocking layer between the color filters, and
wherein an electrode of the sensor electrode layer in a display area is arranged between the plurality of second light-blocking layers and the color light-blocking layer.

19. The display panel of claim 1, further comprising an encapsulation layer covering the plurality of display elements,
wherein the plurality of first light-blocking layers are disposed on the encapsulation layer.

20. The display panel of claim 1, further comprising:
a first organic material layer covering the plurality of first light-blocking layers; and
a second organic material layer covering the plurality of second light-blocking layers,
wherein the plurality of second light-blocking layers are disposed on the first organic material layer, and the color filter layer is disposed on the second organic material layer.
